(19) United States
(12) Patent Application Publication
(10) Pub. No.: US 2005/0158634 A1
(43) Pub. Date: Jul. 21, 2005

(54) Photolithography mask comprising absorber/phase-shifter elements

(76) Inventors: Philippe Thony, S-Joseph de Riviere (FR); Bernard Aspar, Rives (FR); Gilles Fanget, Reaumont (FR)

Correspondence Address: Thelen Reid & Priest, P O Box 640640, San Jose, CA, 95164-0640, US

(21) Appl. No.: 10/513,612

(22) PCT Filed: May 6, 2003
(86) PCT No.: PCT/FR03/01400

(30) Foreign Application Priority Data
May 7, 2002 (FR) 02/05718

(51) Int. Cl. G03F 9/00; G03C 5/00

(52) U.S. Cl. 430/5; 430/322; 430/323; 430/324

(57) ABSTRACT

This invention relates to an insolation mask including a transparent substrate (100) and at least one absorber/phase shifter element (112) embedded in the substrate, so as to form a monolithic assembly with the substrate. Application to photolithography.

### TECHNICAL DOMAIN

This invention relates to a photolithography mask with included absorber/phase shifter elements.

Photolithography masks are largely used for manufacturing components in the fields of microelectronics, microsystems and integrated optics. In particular, they are used to fix the shape and dimensions of components, parts of components, or intermediate structures used for making components.

Then invention is used for applications in the technical fields mentioned above, and particularly for making very small sized patterns using insolation light with short wavelength.

### STATE OF PRIOR ART

Photolithography is one of the fundamental techniques of microelectronics. It uses photosensitive intermediate and sacrificial layers. These layers, for example made of resin, are deposited on layers of material to be treated. After insolation and development, the formed resins can form etching or doping masks for subjacent layers to be treated.

The photosensitive resins themselves are insolated through an insulation mask, to give the required pattern to them. This pattern corresponds to the required pattern, possibly at a larger scale. The insolation light is usually monochromatic coherent light from a laser. An optical system associated with the mask and receiving insulation light forms an image of the mask pattern on the layer of photosensitive resin.

Insolation masks may advantageously be installed in a photo-repeater to successively insolate different fields of a support, according to exactly the same pattern.

FIG. 1 appended illustrates a simplified view of a known type of insolation mask.

The mask in FIG. 1 comprises a transparent substrate 10 made of silica or quartz. There are absorber/phase shifter elements 12 on this substrate. These elements correspond to the insolation pattern or a complementary pattern, depending on whether the photosensitive resin is of the positive or negative type. Absorber/phase shifter elements may be opaque or semi-transparent elements.

Opaque absorber/phase shifter elements, for example such as chromium elements, may be used to make a binary insolation mask. Furthermore, absorber/phase shifter elements made of a semi-transparent material such as a silicon or molybdenum alloy, are used to make an insolation mask with a phase shift. The light that passes through the absorber/phase shifter elements is shifted in phase with respect to the light that passes outside these elements.

There is an overlap film 20 above the mask absorber/phase shift elements. For example, it may be a polymer film. The film 20 is kept at a distance from the absorber/phase shifter elements 12 using a frame 22 bonded on the substrate 10. The essential role of the film is to prevent dust from depositing on the face of the substrate on which the absorber/phase shifter elements are placed.

The image of the mask formed on a photosensitive layer to be insolated corresponds to the image of the absorber/phase shifter elements. In other words, for a conjugated focal plane, the optical system associated with the mask is focussed on the face of the substrate 10 on which the absorber/phase shifter elements are placed. Thus, the spacing between the film 20 and the absorber/phase shifter elements 12 of the mask makes it possible to move the image of any dust or scratches outside the field of sharpness.

The contrast of the blurred image of dust is then sufficiently low so that the resin to be exposed is not sensitive to it.

The development of microelectronics techniques towards the manufacture of ever increasingly fast and high performance components, leads to the production of even smaller photolithography patterns. Within the context of this development, improvements to insulation equipment can apply to optical components for projection of the mask image. For example, it may be necessary to increase their aperture. Another important parameter is the wavelength of insolation light. One trend is to reduce the wavelength by making it change from 193 mm for existing photo-repeaters to 157 nm for future production units. The reduction of the wavelength enables projection of finer details.

However, a difficulty appears with a wavelength as short as 157 nm. This is related to a limited transmission of light through the mask and through the optical projection means.

The mask substrate, and the protection lenses, may possibly be made from materials that could enable satisfactory transmission of light. On the other hand, the overlap film 20 absorbs a large quantity of insolation light for short wavelengths. The same is true for air located in the space between the substrate 10 of the mask and the overlap film 20. High absorption limits the contrast of the projected image and therefore the lithography resolution.

One envisaged solution is to replace the flexible overlap film 20, which is a polymer, by a film made of a hard material with better light transmission properties. However, the use of a hard material for the overlap film may have a greater disturbance on the path of an insolation light beam. This can lead to deformations of the mask image projected onto a layer of photosensitive material to be insolated. Furthermore, placement of an overlap film made of a hard material increases the complexity and manufacturing cost of the masks.

Furthermore, to avoid the absorption of light by air contained in the free space between the substrate and the overlap film, a system may be provided to purge this space before use. However, this operation is difficult and also increases the final cost of the mask.

A complementary illustration of the state of the art can be found in documents (1) and (2), for which complete references are given at the end of the description.

There is another type of mask: alternating PSM or self-aligned type masks. This state of the art is illustrated in document (3), for which a complete reference is given at the end of the description. These masks are provided with chromium patterns and quartz etching for phase shifters. The phase shifters are made initially on the substrate. A chromium layer is then deposited. The chromium patterns are made in this layer. These masks are called SCAA for “Sidewall Chromium Alternating Aperture”.

The production of this type of mask raises the problem that the technological process must include two steps, one for quartz to make the phase mask and the other for chromium to make the chromium mask, these two steps being performed on the same substrate. It is difficult to make a defect free chromium deposit on the etched surface of the substrate. It is also difficult to make patterns in the chromium layer, always due to the topology of the surface (spreading of resin and insolation by electron beam or by laser).

Presentation of the Invention

The purpose of this invention is to propose a photolithography mask without the limitations and difficulties mentioned above.

One purpose in particular is to propose a mask compatible with short insolation wavelengths, and particularly with a wavelength of the order of 157 nm, or even less.

Another purpose is thus to propose a mask that does not introduce any important deformations to the projected image and that does not significantly absorb insolation light.

Another purpose is to propose a mask that does not require a purge and for which the manufacturing cost is moderate.

To achieve these purposes, the invention more precisely relates to a photolithography mask including a transparent substrate, the substrate including a first part of the substrate and a second part of the substrate fixed to the first part of the substrate, at least one absorber/phase shifter element being embedded in the substrate, characterised in that the first part of the substrate is bonded without any added material onto the second part of the substrate.

Although the mask may include only one absorber/phase shifter element, possibly with a complex shape, it generally comprises several elements. In the remainder of the text, reference is made to a plurality of absorber/phase shifter elements.

Absorber/phase shifter elements are considered as being included in the substrate and as forming a monolithic assembly with the substrate, when they are embedded such that the mask does not have any cavity in contact with absorber/phase shifter elements, or when a cavity, if any, is sufficiently small so that it does not significantly absorb a light beam that could pass through the substrate.

Due to the monolithic nature of the mask, it contains very little or no air or gas absorbing the insolation light. Moreover, since absorber/phase shifter elements are included, their main faces that might be exposed to light are covered by the substrate. They are thus protected from dust and scratches, if there are any. More precisely, dust and scratches may appear on an external face of the substrate, in other words outside a plane or a region comprising absorber/phase shifter elements. The spacing between the absorber/phase shifter elements and a surface that could be polluted corresponds to the thickness of the substrate or a part of the substrate that covers the elements, and not a cavity. Furthermore, this type of element can easily be cleaned using standard processes such as chemical baths.

At least one absorber/phase shifter element may be embedded in one of the said parts of the substrate, being exposed with a contact face of the other of the said parts of the substrate. In this embodiment, the second part of the substrate forms a cover that exactly covers the face of the first part of the substrate on which the absorber/phase shifter elements are exposed. The first and second parts may be interchangeable. In other words, each of the two parts may comprise both embedded absorber and phase shifter elements and may act as a cover for the other part. Thus, problems related to the manufacture of alternating PSM type masks are avoided. Each function (phase mask and chromium mask) is made in a substrate that is specific to it before assembly. There is no interference between the two substrates.

The absorber/phase shifter elements may be chosen from among opaque elements, transparent elements and semi-transparent elements with a refraction index different from the refraction index of the substrate, or a combination of such elements.

Advantageously, the first and second parts of the substrate in direct contact with each other may be made from identical materials. This prevents any discontinuity in propagation of light through the mask. The materials may also be chosen to be different to deliberately introduce phase shifts of light. For example, the first and second parts of the substrate are assembled by bonding, and advantageously by molecular bonding.

According to one variant, the absorber/phase shifter elements may also be in contact through an infill material arranged between the first and second parts of the substrate. The absorber/phase shifter elements may be embedded in the first and second parts of the substrate. The absorber/phase shifter elements may also be embedded in the intermediate infill layer and sandwiched between the first and second parts of the substrate.

One of the first and second parts of the substrate, or possibly both parts, may be etched before their assembly such that at least a first part of the substrate has a face with depressions facing a second part of the substrate. The depressions may be filled with an infill material. For example, it may be intermediate material between the parts of the substrate.

The cavities, filled with the infill material, may form light phase shifter elements when the infill material has an optical index different from the optical index of the first and/or second part of the substrate.

Other characteristics and special features of the invention will become clearer from the following description given with reference to the appended figures. This description is given purely for illustrative purpose and is in no way limitative.

### BRIEF DESCRIPTION OF THE FIGURES

FIG. 1, already described, is a simplified diagrammatic section through a known type of photolithography mask,

FIG. 2 is a diagrammatic section through a photolithography mask according to the invention, with a substrate in two parts,

FIG. 3 is a diagrammatic section through a photolithography mask according to the invention, with an intermediate infill material,

FIGS. 4 and 5 are diagrammatic sections through photolithography masks according to the invention and forming variants to the masks in FIGS. 2 and 3,

FIGS. 6 and 7 are diagrammatic sections through photolithography masks according to the invention with phase shifter elements,

FIGS. 8 and 9 are diagrammatic sections through photolithography masks according to the invention and forming variants of the mask in FIG. 7.

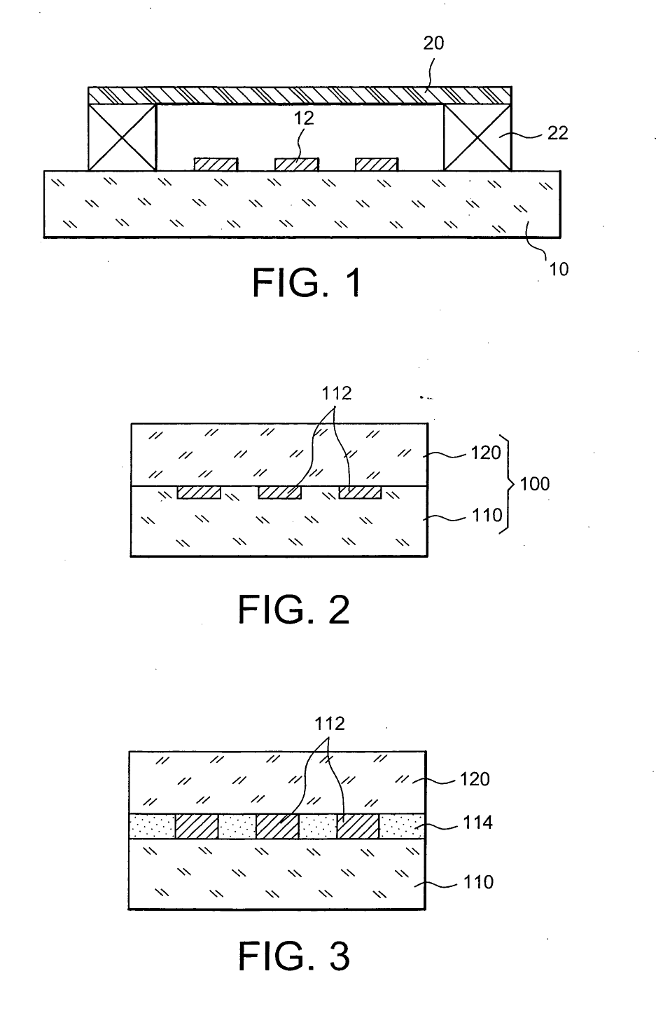

### DETAILED DESCRIPTION OF EMBODIMENTS OF THE INVENTION

In the remaining description, identical, similar or equivalent parts of the different figures are marked by the same reference signs to facilitate the comparison between the figures. Furthermore, and in order to make the figures clearer, not all elements are shown at the same scale.

FIG. 2 shows a mask according to the invention. It comprises a transparent substrate 100, and included in this substrate, light absorber/phase shifter elements 112. The substrate is made of a hard material. For example, it is preferably made of silica or quartz or any other transparent material for a wavelength of the insolation light.

Light absorber/phase shifter elements may be made of an opaque material such as a metal, for example, a layer of chromium. They may also be made of a semi-transparent material, such as MoSi. When a semi-transparent material is used, it can be used to introduce a phase shift in the insolation light. The transmission coefficient of transparent materials is for example of the order of 6 to 12%. The value of the phase shift that exists between beams that pass through the absorber/phase shifter elements and beams that do not pass through them, may be adjusted by acting on the composition and/or the thickness of these elements. The composition and thickness are for example adjusted to introduce a phase opposition into the beams.

Making a mask according to FIG. 2 for example includes etching of cavities in a first part 110 of the substrate, deposition of a layer of material appropriate for fabrication of the absorber/phase shifter elements, then planing this layer stopping on the first part of the substrate. At the end of this operation, absorber/phase shifter elements 1 12 are obtained that are exposed on one face of the first part of the substrate 110. The shape of the elements corresponds to the shape of the previously etched cavities. The mask is completed by bonding a second part of the substrate 120 onto the face on which the absorber/phase shifter elements are exposed.

Bonding may be direct molecular bonding, in other words with no added material. This is achieved by appropriate preparation of polishing and cleaning of the faces of the first and second parts of the substrate brought into contact. For example, a hydrophilic type of bonding may be made. To achieve this, before bringing into contact, the two parts of the substrate are cleaned to obtain good hydrophilic properties (for example an SC1 type chemical cleaning). A mechanical-chemical polishing may be done to attenuate or eliminate surface roughness. A heat treatment may be done after assembly, to increase bonding forces and to give good stability in the long term (for example, this treatment may be applied at 300 K for 2 hours).

The first and second parts of the substrate may be made of different materials, or preferably using the same material. Using the same material means that the path of a light beam passing from the first part of the substrate to the second part of the substrate is not affected.

FIG. 3 shows another possible means of making the photolithography mask. In this example, a layer of opaque or semi-transparent material is deposited on a face of a first part of the substrate 110. This layer is then etched to apply a required pattern to it and thus form one or several absorber/phase shifter elements 112. The interstices between absorber/phase shifter elements are then filled with an infill material 114 that may be transparent or semi-transparent such as molten silica or molten silica modified by the addition of chlorinated or fluorinated compounds. This infill material may also be an organo-mineral glass deposited in solution in a solvent, by centrifuging and annealed (sol-gel process). The choice of this material is not particularly critical. The thickness of the absorber/phase shifter elements 112, and therefore of the infill material, is usually small. Thus, the infill material does not absorb a large quantity of insolation light. It is thus possible to choose a quasi-transparent or transparent infill material. After planing the infill material, for example using a mechanical-chemical polishing process, the first part of the substrate 110 is assembled with the second part of the substrate 120, also called the superstrate, so as to cover the absorber/phase shifter elements 112.

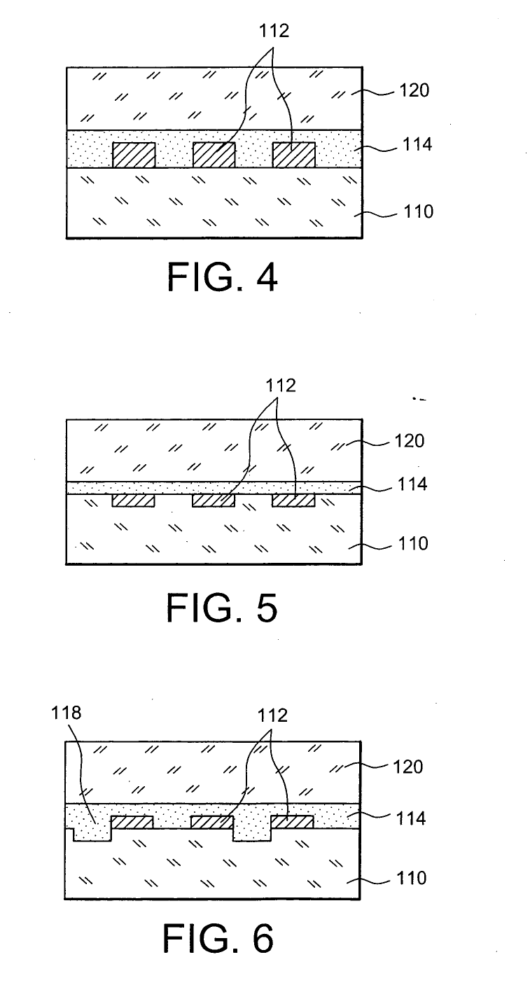

FIG. 4 shows a variant of the photolithography mask in FIG. 3. According to this variant, the infill material covers the absorber/phase shifter elements 112. When the mask is being manufactured, planing of this material does not stop on the absorber/phase shifter elements, but before these elements are reached. During assembly of the first and second parts of the substrate 110, 120, the infill material could be used for bonding by encouraging adhesion of the first and second parts.

FIG. 5 shows a variant of the photolithography mask in FIG. 2. Before assembly of the first and second parts of the substrate 110, 120, a layer of transparent material 114, comparable to the infill material, is deposited on the face of the first part of the substrate 110, on which the absorber/phase shifter elements 112 are exposed. For example, the layer of the transparent material 114 may be a glue.

FIG. 6 shows particular embodiment of a photolithography mask according to the invention in which phase shifter elements 118 formed directly in one of the parts 110 of the substrate, are associated with the absorber/phase shifter elements 112. It is observed that the first part of the substrate 110 has depressions 116 etched from the face on which the absorber/phase shifter elements are placed. The depressions may be etched before or after the formation of absorber/phase shifter elements 112 and are located particularly between the locations planned for these elements. The phase shifter elements 118 are composed of the combination of depressions 116 and an infill material that fills these depressions. In the example illustrated, the depressions are filled with the transparent infill material 114 already mentioned with reference to the previous figures. The depressions 116 are such that a beam passes through the variable thicknesses of the substrate and the infill material. Variable phase shifts may also be introduced in beams as a function of the depth of depressions 116.

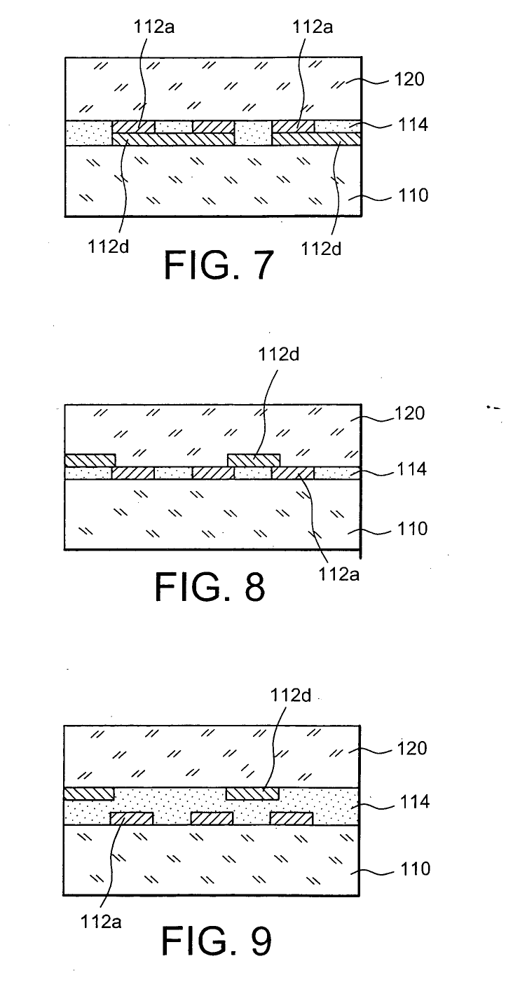

FIG. 7 shows another possible embodiment of a photolithography mask comprising two types of absorber/phase shifter elements 112a, 112d. Two layers of materials are deposited one after the other in the part of the substrate 110 and are formed by etching according to required patterns. These are, in order, a layer of transparent or semi-transparent material with an optical index different from the optical index of the first part of the substrate 110, then a layer of opaque material. These layers are etched to form phase shifter elements 112d and absorber elements 112a corresponding to the transparent/semi-transparent layer and the opaque layer respectively.

It can be observed that the absorber elements 112a can cover and partially conceal phase shifter elements 112d. The space between the absorber and phase shifter elements is filled with the infill material 114 as already described. If necessary, the infill material could also form phase shifter elements.

FIGS. 8 and 9 simply illustrate variant embodiments of the photolithography mask in FIG. 7, also with absorber elements 112a and phase shifter elements 112d. In the case in FIG. 8, the absorber elements 112a are formed on an assembly face of the first part 110 of the substrate, while the phase shifter elements 112d are embedded in the second part 120 of the substrate. A transparent material 114 coats the absorber elements 112a. It can be observed that the absorber elements of the second part of the substrate 120 coincide with some interstices left between the absorber elements of the first part of the substrate. Note that in one embodiment of the mask according to FIG. 8, the phase shifter elements 112d may be solid or gaseous.

In the final example given in FIG. 9, the phase shifter elements 112d are defined on the second part 120 of the substrate for example by etching a layer, and absorber elements 112a are defined on the first part of the substrate 110. The first and second parts are then assembled, by putting the absorber/phase shifter elements facing each other and connecting them together through a layer 114 of transparent infill material. This layer coats the elements.

In one particular embodiment, after the first and second parts of the substrate have been bonded, at least one of the parts is thinned to obtain a substrate thinner than the sum of the thicknesses of the two parts. This facilitates placement of the mask in the equipment.

### Referenced Documents

[1]

“Mechanical analysis of hard pellicles form 157 nm lithography” by Philip L. reu et al., Optical Microlithography XIV, Proceedings of SPIE, vol. 4346 (2001), pages 1166-1174.

[2]

“157-nm Photomask Handling and Infrastructure: Requirements and Feasibility” by Jerry Cullings, Ed Muzio, Optical Microlithography XIV, Proceedings of SPIE, vol. 4346 (2001), pages 52-60.

[3]

“Phase Phirst! An improved strong-PSM paradigm” by Marc D. Levenson et al., Proc. of SPIE 4186, 20^{th} Annual BACUS Symposium on Photomask technology and Management, ed. Brian J. Grenon, Giang T. Dao (January 2001).

1. A photolithography mask including a transparent substrate, the substrate including a first part of the substrate and a second part of the substrate fixed to the first part of the substrate, at least one absorber/phase shifter element being embedded in the substrate, wherein the first part of the substrate is bonded without any added material onto the second part of the substrate.

2. Mask according to claim 1, wherein it includes a first part of the substrate bonded by molecular bonding on a second part of the substrate.

3. Mask according to claim 1, wherein at least one absorber/phase shifter element is embedded in each first and second parts of the substrate.

4. Mask according to claim 1, wherein at least one absorber/phase shifter element is embedded in one of the said parts of the substrate, being exposed with a contact face of the other of the said parts of the substrate.

5. Mask according to claim 1, wherein the absorber/phase shifter element is in contact with an infill material between the first and second parts of the substrate.

6. Mask according to claim 5, wherein at least one element of the mask is sandwiched between a first and a second part of the substrate.

7. Mask according to claim 1, wherein at least one absorber/phase shifter element is chosen from among opaque elements, semi-transparent elements with a refraction index different from the refraction index of the substrate, or a combination of such elements.

8. Mask according to claim 1, wherein at least one part of the substrate has a face with depressions facing a second part of the substrate, the depressions being filled with an infill material.
